(19) United States
(12) Patent Application Publication
(10) Pub. No.: US 2012/0168706 A1
(43) Pub. Date: Jul. 5, 2012

(54) RESISTANCE RANDOM ACCESS MEMORY

(75) Inventors: Tae Won Noh, Seoul (KR); Seo Hyoung Chang, Bucheon-si (KR); Shin Buhm Lee, Gwangju (KR); Bo Soo Kang, Ansan-si (KR)

(73) Assignee: SNU R&DB FOUNDATION, Seoul (KR)

(21) Appl. No.: 13/276,590

(22) Filed: Oct. 19, 2011

(30) Foreign Application Priority Data
Jan. 3, 2011 (KR) 10-2011-0000131

(51) Int. Cl. H01L 45/00

(52) U.S. Cl. 257/4; 257/E45.003

(57) ABSTRACT

The present disclosure relates to a resistance random access memory comprising a first electrode, a thin film layer formed on the first electrode and including a resistance switching layer and a switching layer bonded to each other, and a second electrode formed on the thin film layer, and relates to a method of manufacturing the same.

### FIELD OF THE INVENTION

The present disclosure relates to a resistance random access memory and a method of manufacturing the same. To be specific, the present disclosure relates to a resistance random access memory including a thin film layer formed by bonding two layers having a resistance switching characteristics and a switching characteristics, respectively.

### BACKGROUND OF THE INVENTION

Silicon-based memory devices making up the majority of semiconductor memory devices may be faced with a quantum-mechanical limit such as tunneling as the memory devices are reduced in size. Thus, a demand for a new concept of a memory device has been increased. As a candidate for a next-generation memory device, there has been suggested a resistance random access memory (RRAM) using bipolar resistance switching phenomenon in oxides.

The bipolar resistance switching refers to a phenomenon in which low and high resistance states are alternately switched by polarity of a voltage applied. Recently, the resistance random access memory has been given a lot of attention since it can be operated in a non-volatile nanometer-sized device at a very high operating speed by using the bipolar resistance switching phenomenon.

In order to increase an integration density of the resistance random access memory, a conventional 3-dimensional (3D) crossbar architecture is needed. However, to implement the 3D crossbar architecture, two significant problems may be encountered. A first thing is a sneak path problem, which is the misreading of information originating from an undesirable leakage current of neighboring devices when information stored in a certain device of the crossbar architecture needs to be read. The conventional crossbar architecture uses a Si-based transistor to select a certain resistance random access memory. Thus, a second thing is a scaling limit in implementing a high integration density of the resistance random access memory using such a transistor.

### BRIEF SUMMARY OF THE INVENTION

The present disclosure provides a resistance random access memory including a thin film layer formed by bonding a resistance switching layer and a switching layer to each other without using an intermediate electrode to solve a sneak path problem as a limiting factor of high integration.

However, the problems to be solved by the present disclosure are not limited to the above description and other problems can be clearly understood by those skilled in the art from the following description.

In accordance with an aspect of the present disclosure, there is provided a resistance random access memory comprising a first electrode, a thin film layer formed on the first electrode and including a resistance switching layer and a switching layer bonded to each other, and a second electrode formed on the thin film layer.

In accordance with another aspect of the present disclosure, there is provided a resistance random access memory array comprising: a plurality of first electrode lines formed in a first direction; thin film layers formed on each of the plurality of first electrode lines and including resistance switching layers and switching layers bonded to each other; and a plurality of second electrode lines formed on the thin film layers in a second direction.

A resistance random access memory in accordance with the present disclosure uses a thin film architecture in which a bi-directional switching layer instead of a transistor conventionally used as a switching element is directly bonded to a resistance switching layer, and thus, the sneak path problem can be prevented. Further, unlike a conventional memory device including an intermediate electrode, the resistance random access memory in accordance with the present disclosure has an architecture in which the switching layer and the resistance switching layer are bonded to each other without an intermediate electrode, and, thus, a resistance random access memory array of a high integration density can be fabricated and a process of fabricating the memory array can be simplified.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic diagram showing a sneak path problem in a conventional resistance random access memory;

FIGS. 2A to 2C are a cross sectional view of a resistance random access memory in accordance with an embodiment of the present disclosure;

FIG. 3 is a schematic diagram showing that a resistance random access memory in accordance with an example of the present disclosure solves a sneak path problem;

FIG. 4 is a perspective view of a resistance random access memory array in accordance with an embodiment of the present disclosure;

FIG. 5 shows a resistance random access memory array in accordance with an example of the present disclosure and a graph showing a performance test thereof;

FIG. 6 shows a result of a performance test in which a pulse voltage is applied to a resistance random access memory array in accordance with an example of the present disclosure; and

FIG. 7 shows a result of a performance test of a resistance random access memory in accordance with an example of the present disclosure in a minimum electrode size by using a conducting atomic force microscopy (C-AFM).

### DETAILED DESCRIPTION OF THE INVENTION

Hereinafter, embodiments and examples of the present disclosure will be described in detail with reference to the accompanying drawings such that the present disclosure may be readily implemented by those skilled in the art.

However, it is to be noted that the present disclosure is not limited to the embodiments and examples but can be realized in various other ways. In the drawings, parts irrelevant to the description are omitted for the simplicity of explanation, and like reference numerals denote like parts through the whole document.

Through the whole document, the terms “comprises or includes” and/or “comprising or including” used in the document means that one or more other components, steps, operation and/or existence or addition of elements are not excluded in addition to the described components, steps, operation and/or elements.

Through the whole document, the terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party.

Through the whole document, the terms “bipolar resistance switching element” means an element in which a voltage required for switching reversible two resistance states has two (both) polarities.

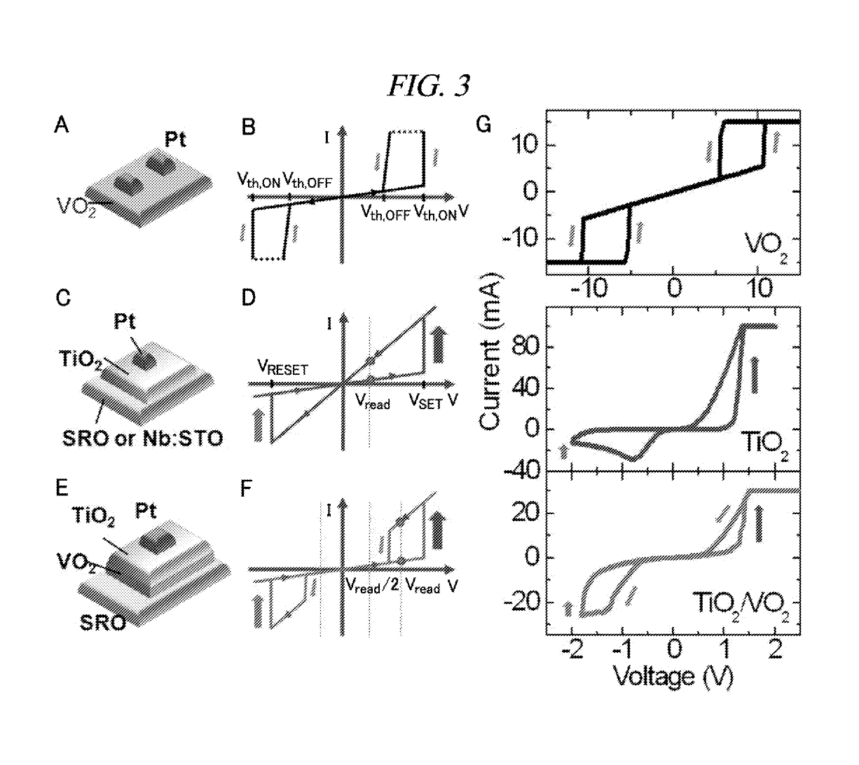

Through the whole document, the terms “bi-directional switching” element means an element or a device capable of performing a rectifying action in both directions (see FIG. 3(F)).

A resistance random access memory in accordance with an aspect of the present disclosure may include a first electrode, a thin film layer formed on the first electrode and including a resistance switching layer and a switching layer bonded to each other, and a second electrode formed on the thin film layer.

In the present disclosure, the thin film layer including the resistance switching layer and the switching layer bonded to each other may have an architecture in which the resistance switching layer and the switching layer are stacked with bonding each other, there is no intermediate electrode between the resistance switching layer and the switching layer, and the resistance switching layer and the switching layer are in a direct contact with each other through an interface. Therefore, the thin film layer includes the resistance switching layer and the switching layer bonded to each other. If these layers are made of a material serving as a resistance switching layer and a material serving as a switching layer, respectively, there is no limit to a material of each layer. By way of example, the resistance switching layer and the switching layer constituting the thin film layer may be made of the same oxide, or may be made of oxides different from each other so as to form a heterojunction structure.

In an embodiment, if the resistance switching layer is made of a material that has bipolarity, there is no limit to use of a material of the resistance switching layer. In an embodiment, the resistance switching layer may include an oxide, a polymer or a solid electrolyte. By way of example, the oxide may include at least one selected from the group consisting of, but not limited to, a Ni oxide, a Cu oxide, a Ti oxide, a Co oxide, a Hf oxide, a Zr oxide, a Zn oxide, a W oxide, a Nb oxide, a TiNi oxide, a LiNi oxide, an Al oxide, an InZn oxide, a V oxide, a SrZr oxide, a SrTi oxide, a manganite oxide, a Cr oxide, a Fe oxide, and a Ta oxide.

As for the switching layer, if it is made of a material that has a bi-directional switching characteristic and has been typically used in the art, there is no limit to a material of the switching layer. In an embodiment, the switching layer may include, but is not limited to, an oxide having a bi-directional switching characteristic. By way of example, the switching layer may include at least one selected from the group consisting of, but not limited to, a V oxide, a Ni oxide, a Ti oxide, a Zr oxide, and a Nb oxide.

In an embodiment, each of the resistance switching layer and the switching layer constituting the thin film layer may be independently formed in a single layer or multiple layers. Further, if the resistance switching layer and the switching layer are formed in multiple layers, the numbers of layers of the resistance switching layer and the switching layer may be the same or different. In an embodiment, the resistance switching layer formed in multiple layers or the switching layer formed in multiple layers may be made of the same oxide or different oxides.

In an embodiment, the resistance switching layer and the switching layer may independently have a thickness ranging from, but not limited to, tens of nanometer to micrometer. By way of example, if it is possible to obtain a curve I-V as depicted in FIG. 3(F) considering a relationship between resistance and voltage in the resistance switching layer and the switching layer, their thicknesses may not be limited.

By way of example, the switching layer may have a thickness ranging from, but not limited to, about 50 nm to about 200 nm, and the resistance switching layer may have a thickness ranging from, but not limited to, about 40 nm to about 150 nm.

An electrode (a first electrode or a second electrode) employed in the present disclosure may not be limited if it is typically used for a resistance random access memory in the art. The first electrode and the second electrode may independently include a metal electrode or an oxide electrode, respectively. By way of example, the electrode is a metal electrode, it may include at least one selected from the group consisting of, but not limited to, Pt, Ir, Al, Ti, TiN, Ag, Bi, Hf, and Ni. Further, if the electrode is an oxide electrode, it may include at least one electrode selected from the group consisting of, but not limited to, a lanthanum-nickel oxide, a strontium-ruthenium oxide (SrRuO₃), an indium-tin oxide (ITO), an iridium oxide, and a strontium-titanium oxide. In an embodiment, each of the first and second electrodes may be, but is not limited to, a transparent electrode formed of a transparent conductive oxide. The transparent conductive oxide may not be limited and can be selected from oxides publicly known in the art.

A method of manufacturing the resistance random access memory in accordance with another embodiment of the present disclosure may include forming a first electrode on a substrate, forming a thin film layer including a junction structure in which a resistance switching layer and a switching layer are bonded to each other on the first electrode, and forming a second electrode on the thin film layer.

In an embodiment, forming the thin film layer may include, but is not limited to, forming the resistance switching layer and the switching layer bonded to the resistance switching layer in sequence on the first electrode, or forming the switching layer and the resistance switching layer bonded to the switching layer in sequence on the first electrode.

In an embodiment, the thin film layer may be formed by, but not limited to, chemical vapor deposition, pulse laser deposition, sputtering, atomic layer deposition, molecular beam deposition or electron beam deposition.

In an embodiment, the method of manufacturing the resistance random access memory may include, but is not limited to, forming a plurality of the first electrodes and a plurality of the second electrodes in which the first electrodes may cross with the second electrodes and placing the thin film layer at crossing points of the first electrodes and the second electrodes.

The method of manufacturing the resistance random access memory may include all the above-descriptions regarding the resistance random access memory and other published disclosures regarding a method of manufacturing a resistance random access memory. For the sake of convenience, the descriptions thereof will be omitted.

A resistance random access memory array in accordance with another aspect of the present disclosure may include a plurality of first electrode lines formed in a first direction, a thin film layer formed on the first electrode line and including a resistance switching layer and a switching layer bonded to each other, and a plurality of second electrode lines formed in a second direction on the thin film layer.

In an embodiment, the resistance random access memory array may include, but is not limited to, the plurality of first electrode lines and the plurality of second electrode lines in which the plurality of first electrode lines may cross with the plurality of second electrode lines and the thin film layer positioned at crossing points of the plurality of first electrode lines and the plurality of second electrode lines.

In an embodiment, the resistance random access memory array may have an integration density of, but not limited to, about 1.6 Tb/inch² or more.

In an embodiment, the resistance random access memory array may have, but is not limited to, a 3-dimensional crossbar architecture in which the plurality of first electrode lines may cross with the plurality of second electrode lines and they may be repeatedly stacked and the thin film layers may be formed at crossing points of the plurality of first electrode lines and the plurality of second electrode lines.

The resistance random access memory array may include all the above-descriptions regarding the resistance random access memory and the method of manufacturing the same and other published disclosures regarding a resistance random access memory and a resistance random access memory array. For the sake of convenience, the descriptions thereof will be omitted.

Hereinafter, referring to the accompanying drawings, there will be explained a resistance random access memory, a method of manufacturing the same, and a resistance random access memory array. However, the present disclosure will not be limited to the descriptions below.

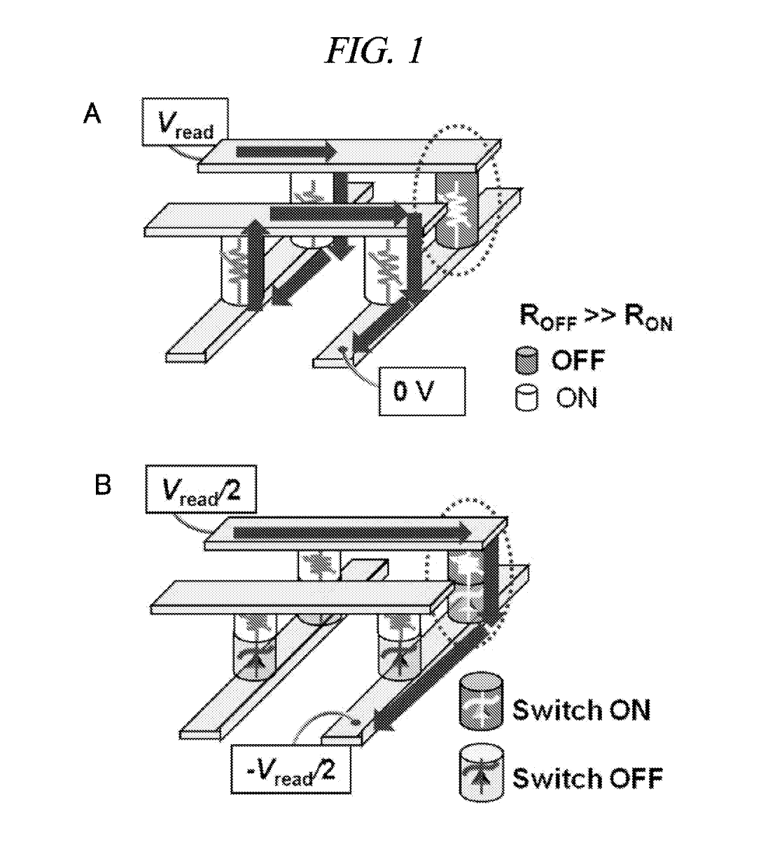

Referring to FIG. 1, a sneak path problem will be explained in more detail. As depicted in FIG. 1(A), a resistance random access memory array may include a resistance switching layer (or a memory layer) which may be formed between word lines (first electrode) and bit lines (second electrode) of 2-dimensional crossbar architecture. As depicted in FIG. 1(A), when an external voltage is applied between the word lines and the bit lines, information of an undesirable element 4 may be read instead of information of a desirable element 1, which is referred to as “sneak path”. Such a sneak path problem can be solved by additionally forming a switching material between the resistance switching layers and the electrodes. In an embodiment, as depicted in FIG. 1(B), the switching material may turn off the switch to prevent a leakage current from flowing through an undesirable element, information of the desirable element 1 can be read accurately.

As depicted in FIG. 1(B), as a conventional method to solve the sneak path problem, there has been suggested a method of forming a switching element between a resistance switching layer and an electrode. However, it is difficult to achieve high integration in such a switching element and the switching element needs to be improved for a real operation. By way of example, the switching element may be based mainly on a unipolar resistance switching material, which requires a very high operating voltage and shows a very large fluctuation during operation. Further, when the conventional switching element is made of a bipolar resistance switching material, generally, at least one intermediate electrode is formed between a resistance switching layer and the bi-directional switching material. In this case, it is difficult to achieve high integration density of an element.

Thus, in order to prevent the above-described sneak path problem, the present disclosure employs a thin film layer having a junction structure in which a resistance switching layer having bipolarity and a switching layer are bonded to each other instead of a transistor or a diode used as a conventional switching element. By way of example, the thin film layer may be formed of, but not limited to, a heterojunction oxide layers in which oxides different from each other may be stacked.

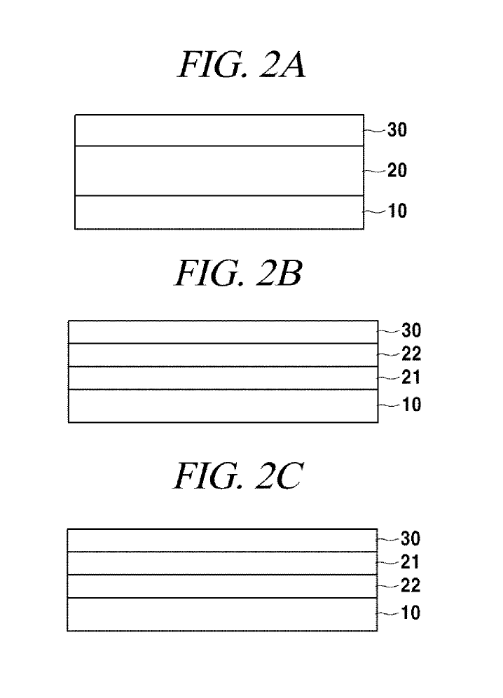

FIG. 2 is a cross sectional view of a resistance random access memory in accordance with the present disclosure. The resistance random access memory may include a first electrode 10, a thin film layer 20 formed on the first electrode 10, and a second electrode 30 formed on the thin film layer 20. To be more specific, the thin film layer 20 may include a resistance switching layer 21 and a switching layer 22. The thin film layer may not be limited if it has an architecture in which the resistance switching layer and the switching layer are stacked in sequence. In the thin film layer, the resistance switching layer and the switching layer may be formed in sequence as depicted in FIG. 2B, or on the contrary to this, the resistance switching layer may be formed on the switching layer as depicted in FIG. 2B. The resistance random access memory in accordance with the present disclosure may have a simple architecture without an intermediate electrode that has been used in the above-described conventional resistance random access memory, and, thus, it may become easy to stack multiple memories.

Hereinafter, an example of the present disclosure will be explained with reference to FIG. 3.

A resistance random access memory was manufactured by forming a switching layer containing VO₂ on a Pt electrode and forming a resistance switching layer containing TiO₂ on the switching layer. To be more specific, TiO₂ was deposited on a Nb: SrTiO₃ single crystalline substrate and VO₂ was deposited on an Al₂O₃ single crystalline substrate by using a pulse laser deposition system. A TiO₂/VO₂ heterostructure thin film layer was grown on a Pt (150-nm thick)/TiOₓ/SiO₂/Si substrate by using the pulse laser deposition system. The switching layer (VO₂) was deposited at about 600° C. and a chamber pressure of about 15 mTorr. Further, the resistance switching layer (TiO₂) was grown at about 600° C. The resistance switching layer can be deposited under, but not limited to, various oxygen partial pressures. By way of example, the oxygen partial pressure for the deposition of the resistance switching layer (TiO₂) was about 5×10⁻⁶ Torr for about 20 minutes and about 50 mTorr for about 5 minutes. Pt (50-nm thick) was deposited as an upper electrode at room temperature by on-axis sputtering and patterned by photolithography.

Referring to FIGS. 3(A) and 3(B), the switching layer (VO₂) may have two resistance states depending on a magnitude of applied voltage. To be more specific, when the applied voltage becomes greater than a threshold voltage Vₜₕ, it becomes in an ON state, and when the applied voltage becomes smaller than Vₜₕ, it becomes in an OFF state. The switching layer (VO₂) has a hysteretic behaviour due to a first-order phase transition, but it is not essential for operation of a switch element. As depicted in FIGS. 3(C) and 3(D), the resistance switching layer (TiO₂) had bistable states with high and low resistances which will work as OFF and ON states, respectively. The OFF state can be changed to the ON state by applying a positive voltage, called “set voltage V_{SET}”, on the resistance switching layer. Likewise, there is a reversible change from ON to OFF by applying a reset voltage.

Referring to FIGS. 3(E) and 3(F), when V_{read} is applied, information of the resistance switching layer can be read, and, thus, it may be possible to distinguish whether the resistance switching layer is in either the ON or OFF state. On the other hand, when V_{read}/2 is applied, the switching layer may be always in the OFF state, and even if the resistance switching layer is in the ON state, the whole resistance may be in the OFF state. That is, if a voltage smaller than Vₜₕ is applied, the switching layer may prevent a current flowing through the resistance random access memory. Therefore, in order to operate the resistance random access memory, it has to be Vₜₕ<|V_{RESET}| and V_{SET}. In case of V_{read/2}<Vₜₕ<V_{read}, the sneak path problem can be prevented.

To test feasibility of the resistance random access memory (one bipolar resistive memory combined with one switch, 1S-1BR) in accordance with the present disclosure, actually, VO₂, TiO₂, and the TiO₂/VO₂ thin film layer was deposited as depicted 3a, 3c and 3e and an electric measurement was performed as depicted in FIG. 3(G). As depicted in top two drawings of FIG. 3(G), if a single layer of TiO₂ (or VO₂) is deposited, it can be found that the TiO₂ resistance switching layer (or a VO₂ switching layer) was operated properly. A resistance ratio between ON and OFF states of TiO₂ was about 10⁴. If only TiO₂ is used, neighboring TiO₂ elements in the ON state in the crossbar architecture may cause a sneak path problem in which information of element required to be read cannot be read. A lower drawing of FIG. 3(G) shows experimental data of I-V characteristics of the TiO₂/VO₂ thin film layer, which was very similar to those of an ideal 1S-1BR.

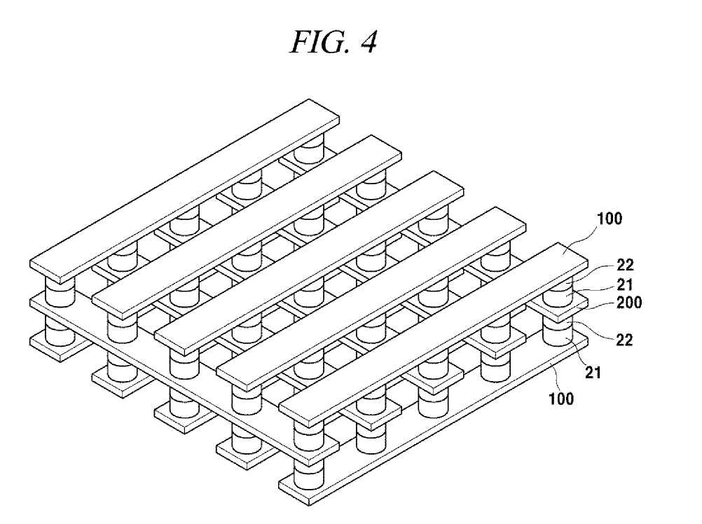

FIG. 4 is a perspective view of the resistance random access memory array in accordance with the present disclosure. To be more specific, referring to FIG. 4, the resistance random access memory array may include a plurality of first electrode lines 100 formed in a first direction, thin film layers 20 formed on the first electrode lines 100, and a plurality of second electrode lines 200 formed in a second direction on the thin film layers. To be more specific, referring to FIG. 4, the resistance random access memory array may have a crossbar architecture in which the first electrode lines 100 may cross with the second electrode lines 200 and the thin film layers including the resistance switching layers 21 and the switching layers 22 bonded to each other may be formed at crossing points of the plurality of first electrode lines 100 and the plurality of second electrode lines 200. The plurality of first electrode lines cross with the plurality of second electrode lines so as to be stacked, so that it may be possible to manufacture the resistance random access memory array of high integration having a 3-dimensional crossbar architecture.

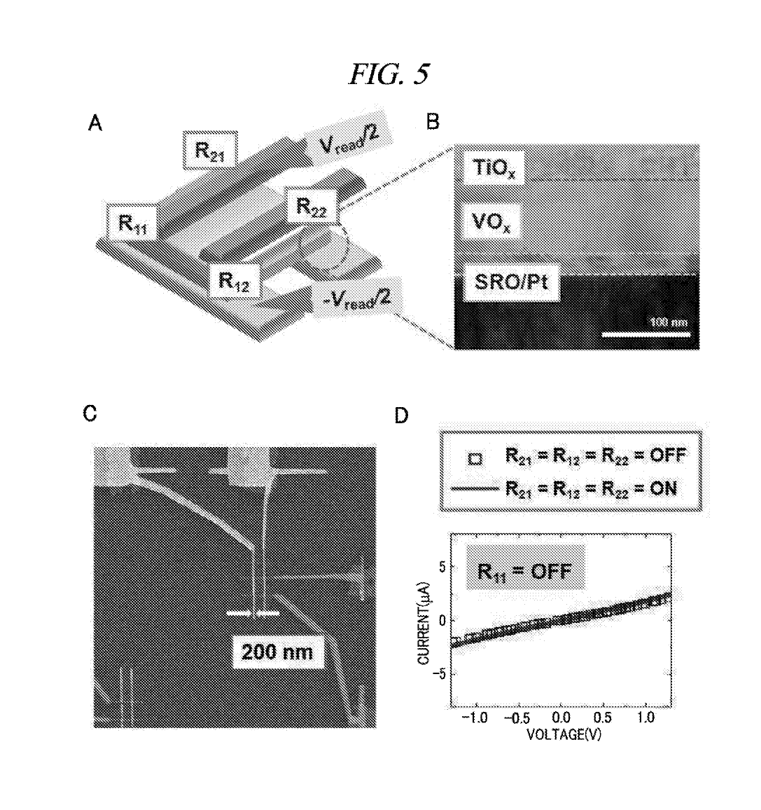

FIG. 5(A) is a perspective view of a 2×2 resistance random access memory array in accordance with an example of the present disclosure. A first electrode (Pt) of the resistance random access memory array was grown on SiO₂/Si by on-axis sputtering and e-beam lithography. A TiO₂/VO₂—thin film layer may be formed on the first electrode regardless of whether or not a buffer layer (SrRuO₃: SRO) exists on the first electrode. The TiO₂/VO₂ thin film layer was patterned by e-beam lithography and a second electrode Pt was formed on the patterned TiO₂/VO₂ thin film layer at room temperature by on-axis sputtering. A line width of the Pt electrode was in a range of from about 200 nm to about 1000 nm.

Referring to FIG. 5(B), a cross section of the resistance random access memory array was observed with a transmission electron microscope (TEM), and as a result of the observation, it was found that the TiO₂/VO₂ thin film layer was formed on the Pt substrate. FIG. 5(C) shows a top view of the resistance random access memory array having a size of about 200 nm×200 nm. As a result of measurement of I-V characteristics of a resistance random access memory array, it was found that the I-V characteristics of the TiO₂/VO₂ thin film layer shown in FIG. 5 was the same as those of an ideal 1S-1BR structure. Referring to FIG. 5(D), in the resistance random access memory array including the TiO₂/VO₂ thin film layer, the sneak path problem did not occur, and it was found that an OFF state of R₁₁ element (see FIG. 5(A)) can be read while all the other elements are in ON state.

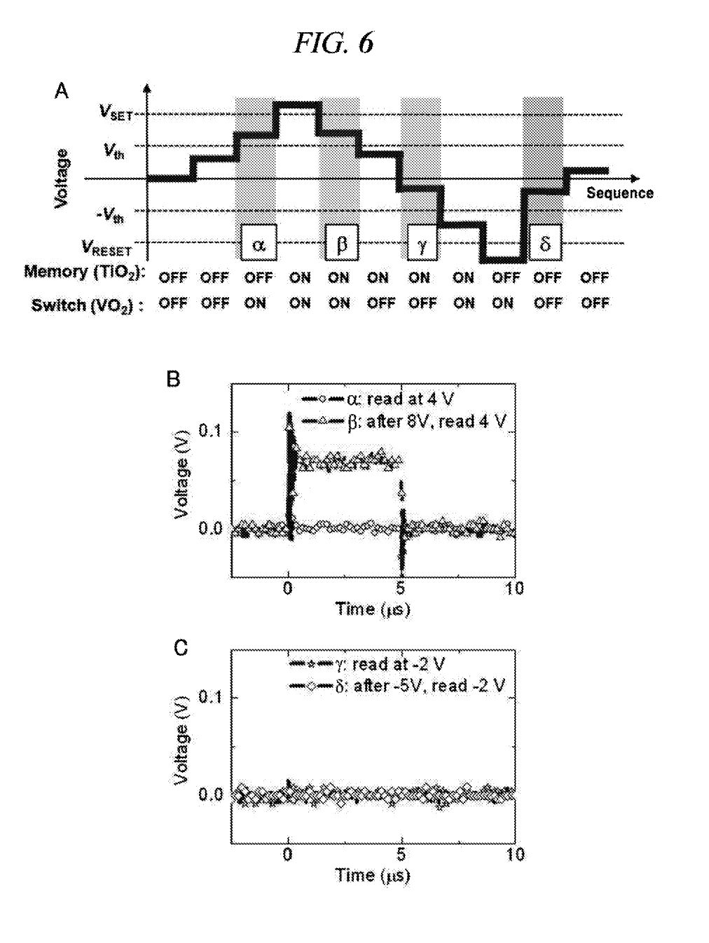

In a resistance random access memory array including a thin film layer in accordance with the present disclosure, the resistance switching layer and the switching layer may be in different states from each other. To be more specific, referring to FIG. 6(A), it can be seen that the resistance switching layer and the switching layer may be in different states within a TiO₂/VO₂ thin film layer depending on a magnitude of an applied pulse. To be more specific, referring to FIG. 6(A), both the resistance switching layer and the switching layer may be in OFF states. With increase of an applied voltage, when the switching layer exceeds a threshold voltage Vₜₕ, the switching layer may be turned ON state without a change in the resistance switching layer (a stage). When the voltage is further increased and it reaches a set voltage V_{SET}, a set operation occurs and both the resistance switching layer and the switching layer may become in ON states. While the applied voltage is greater than Vₜₕ, the ON state may be continued (β stage). When the applied voltage is lower than Vₜₕ, the switching layer may be turned OFF state but the resistance switching layer may still be in an ON state (γ stage). At a negative voltage, of which a magnitude is −Vₜₕ, the switch may be turned into ON state. Then, when the applied voltage is greater than V_{RESET}, the resistance switching layer may be turned from an ON state to an OFF state. When the voltage is lower than Vₜₕ, both the resistance switching layer and the switching layer may be in OFF states (δ stage).

FIGS. 6(B) and 6(C) show a result of observation of performance of a resistance random access memory array including a thin film layer in accordance with the present disclosure by using pulse measurement. To test the sneak path problem, all resistance switching layer and switching layer were initialized in OFF states. Referring to FIG. 6(B), a magnitude of a pulse voltage applied in an element 1 (see FIG. 1(A)) exceeded Vₜₕ so that information of the resistance layer in different stages a and b can be read, which demonstrates that the resistance random access memory array in accordance with the present disclosure may be operated as a non-volatile memory. Further, referring to FIG. 6(C), when the applied pulse voltage is lower than Vₜₕ, although the resistance switching layer is in an ON state and an OFF state differently from each other, it can be seen that there is no difference in output signals of the resistance random access memory array at the γ stage and the δ stage. That is, if a voltage smaller than Vₜₕ is applied to the resistance random access memory array of the present disclosure, all elements of the memory array may become in OFF states and the sneak path problem may not occur.

The above-described I-V measurement was performed at room temperature by using a semiconductor parameter analyser (Agilent 4155C, Agilent Technologies). To prevent dielectric breakdown, a current was limited to a maximum value (a compliance current value). The pulse measurement was performed at room temperature by using a YOKOGAWA FG300 synthesized function generator and a YOKOGAWA DL7100 digital oscilloscope. The C-AFM measurement was performed at a Park system (XE-100) with a platinum-coated tip.

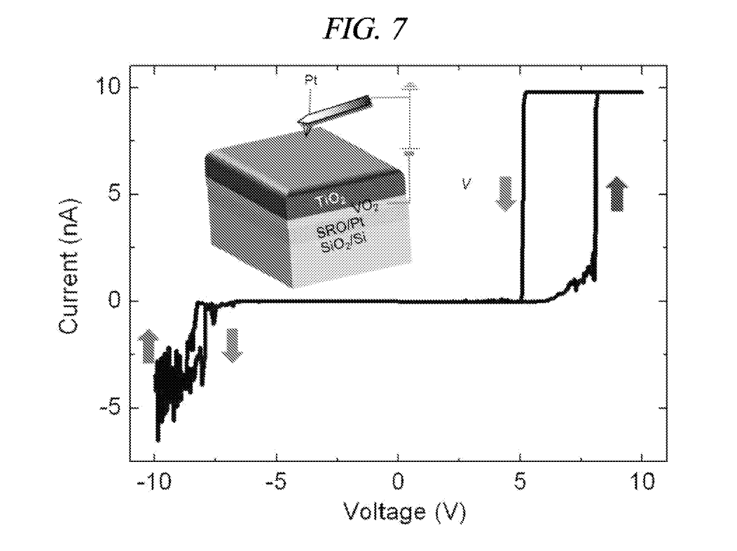

FIG. 7 is a graph as a result of local I-V measurement by using a C-AFM tip to confirm scaling limit of the resistance random access memory array of the present disclosure for proper operation. In the above-described experiment, if the tip of the C-AFM is as large as the electrode, it may be a circle having a diameter of about 10 nm. The above-mentioned C-AFM experiment demonstrates that it may be possible to operate with a memory device size (F=10 nm) and if a 2-dimensional nanocrossbar memory is manufactured with TiO₂/VO₂ element of the present disclosure, it may be possible to obtain an integration density of about 1.6 Tb/inch².

As depicted in FIG. 7, as a size of the electrode is decreased, a reset current may be decreased to about 10⁻⁸ A, which is smaller than a reset current (10⁻⁵ A) of other typical devices. Such a decrease in the reset current may have a great effect on improvement in reliability of operations.

The above-described embodiments and examples are provided for the purpose of illustration of the present disclosure but the present disclosure is not limited thereto. It would be understood by those skilled in the art that various changes and modifications may be made without changing technical conception and essential features of the present disclosure described in the accompanying claims.

### EXPLANATION OF CODES

10: First electrode
20: Thin film layer
21: Resistance switching layer
22: Switching layer
30: Second electrode
100: First electrode line(s)
200: Second electrode line(s)

What is claimed is:

1. A resistance random access memory comprising:
a first electrode;
a thin film layer formed on the first electrode and including a resistance switching layer and a switching layer bonded to each other; and
a second electrode formed on the thin film layer.

2. The resistance random access memory of claim 1,
wherein the resistance switching layer contains a material that has a bipolar resistance switching characteristic.

3. The resistance random access memory of claim 1,
wherein the resistance switching layer contains at least one selected from the group consisting of a Ni oxide, a Cu oxide, a Ti oxide, a Co oxide, a Hf oxide, a Zr oxide, a Zn oxide, a W oxide, a Nb oxide, a TiNi oxide, a LiNi oxide, an Al oxide, an InZn oxide, a V oxide, a SrZr oxide, a SrTi oxide, a manganite oxide, a Cr oxide, a Fe oxide, and a Ta oxide.

4. The resistance random access memory of claim 1,
wherein the switching layer contains a material that has a bi-directional switching characteristic.

5. The resistance random access memory of claim 1,
wherein the resistance switching layer contains at least one selected from the group consisting of a V oxide, a Ni oxide, a Ti oxide, a Zr oxide, and a Nb oxide.

6. The resistance random access memory of claim 1,
wherein the first electrode and the second electrode independently include a metal electrode or an oxide electrode.

7. The resistance random access memory of claim 1,
wherein the resistance switching layer and the switching layer is independently formed in a single layer or multiple layers.

8. A resistance random access memory array comprising:
a plurality of first electrode lines formed in a first direction;
thin film layers formed on each of the plurality of first electrode lines and including a resistance switching layers and a switching layers bonded to each other; and
a plurality of second electrode lines formed on the thin film layers in a second direction.

9. The resistance random access memory array of claim 8,
which forms a 3-dimensional crossbar architecture, wherein the plurality of first electrode lines and the plurality of second electrode lines are repeatedly stacked with crossing each other and the thin film layers are formed at crossing points of the plurality of first electrode lines and the plurality of second electrode lines.
